(19) United States
(12) Patent Application Publication
(10) Pub. No.: US 2006/0017526 A1
(43) Pub. Date: Jan. 26, 2006

(54) Balanced gyrator and devices including the balanced gyrator

(75) Inventor: John Barry Hughes, Hove (GB)

Correspondence Address: PHILIPS INTELLECTUAL PROPERTY & STANDARDS, P.O. BOX 3001, BRIARCLIFF MANOR, NY, 10510, US

(73) Assignee: Koninklijke Philips Electronics N.V.

(21) Appl. No.: 10/500,501

(22) PCT Filed: Dec. 16, 2002
(86) PCT No.: PCT/IB02/05494

§ 371 Date: Jun. 29, 2004

(30) Foreign Application Priority Data
Jan. 4, 2002 (GB) 0200094.1

(51) Int. Cl. H03H 11/00

(52) U.S. Cl. 333/215

(57) ABSTRACT

A balanced gyrator comprises interconnected pairs of single-ended inverting class AB transconductors (TC1 to TC4) fabricated from MOSFETs together with common mode feedback circuits (26) connected between balanced inputs (18, 19) and outputs (22, 23). Peaking of the frequency response resulting from distortion due to the creation of a high frequency parasitic feedthrough path in the transconductors is overcome by the provision in each of the transconductors (TC1 to TC4) of a non-reciprocal feedback capacitance (Cf) which renders the feedthrough capacitance reciprocal thereby neutralising the feedthrough capacitance of the gyrator. The devices include a filter (FIG. 8, not shown) and a transceiver (FIG. 10, not shown).

### TECHNICAL FIELD

The present invention relates to a balanced gyrator and to devices, such as gyrator filters and integrated transceivers including at least one of the balanced gyrators.

### BACKGROUND ART

Gyrator filters are frequently used in low power channel filters for wireless transceivers. Currently there is an interest in being able to fabricate complete integrated transceivers/receivers in MOS technology. Channel filters may comprise MOS gyrators which suffer from capacitive feedforward which is the result of non-reciprocal gate-drain capacitance in its MOSTs and this is results in filters with a distorted high frequency response. Gyrators comprise transconductor feedback pairs and ideally transconductors linearly convert an input voltage into an output current with both input and output ports presenting an infinite impedance. A typical transconductor feedback pair is shown in FIG. 1 in which one transconductor 10 is inverting and the other transconductor 12 is non-inverting.

FIG. 2 shows an embodiment of a balanced class AB transconductor which comprises two pairs of MOS transistors, each pair comprising a p-type transistor 14 and a n-type transistor 16 having their drain electrodes coupled together, their source electrodes connected to respective supply voltage lines V_{dda} and Vₛₛ, their gate electrodes connected together with a common junction of each pair of gate electrodes being connected to a respective input terminal 18, 20, and their respective interconnected drain electrodes coupled to output terminals 22, 24. A common mode feedback (cmfb) circuit 26 is coupled between the input terminals 18, 20 to provide dc stability.

A problem with a balanced gyrator such as that shown in FIG. 3 using two balanced class AB transconductors 10, 12 with the output connections of the feedback transconductor 12 crossed-over is that the capacitances occurring naturally between the drains and gates of the transistors forming the transconductors create a high frequency parasitic feedthrough path and this produces high frequency peaking in the filter's frequency response. This may be mitigated by using very small transistors in the transconductors but in practice this results in very poor matching.

Referring to FIGS. 4 and 5 this problem may be understood by initially considering the capacitances between the gate g and the drain d of a MOSFET as shown in FIG. 4. Y. P. Tsividis, “Operation and Modeling of the MOS transistor”, McGraw-Hill, ISBN 0-07-065381, pp. 370 to 372 points out that transistors which operate in saturation SAT, see FIG. 5, such as those of the transconductors used in the balanced gyrators to which the present invention relates, have intrinsic capacitances Cgs, Cdg and Cgd given by:

$$\begin{matrix}{C}_{gs} = - \frac{δ {Q}_{g}}{δ {V}_{s}} = \frac{2}{3} \cdot {C}_{ox} & ( 1 ) \\ {C}_{dg} = - \frac{δ {Q}_{d}}{δ {V}_{g}} = \frac{4}{15} \cdot {C}_{ox} & ( 2 ) \\ {C}_{gd} = - \frac{δ {Q}_{g}}{δ {V}_{d}} = 0 & ( 3 )\end{matrix}$$

The MOSFET also has an extrinsic capacitance, C_{gdol}, due to gate-drain overlap and stray fields between the gate and the drain contacts.

The transconductor has a feedforward capacitance, C_{ff}, and a feedback capacitance, C_{fb}, where:

$$\begin{matrix}{C}_{ff} = {C}_{dg} + {C}_{gdol} = \frac{2}{5} \cdot {C}_{gs} + {C}_{gdol} & ( 4 ) \\ {C}_{fb} = {C}_{gd} + {C}_{gdol} = {C}_{gdol} & ( 5 )\end{matrix}$$

Clearly the capacitance is non-reciprocal, i.e. C_{ff}≠C_{fb}, and simple neutralisation techniques using simple (reciprocal) capacitances are useless.

### DISCLOSURE OF INVENTION

A first object of the present invention is to mitigate the effects of the high parasitic feedthrough path on the performance of a balanced gyrator.

A second object of the present invention is to avoid or reduce distortion in the frequency response of a filter implemented using balanced gyrators.

According to one aspect of the present invention there is provided a balanced gyrator comprising a plurality of interconnected feedforward and feedback MOS single-ended transconductors, balanced inputs and outputs, common mode feedback means coupled respectively between the balanced inputs and outputs, and means for providing each of the transconductors with a non-reciprocal feedback capacitance for rendering reciprocal the feedthrough capacitance of the transconductor thereby neutralising the feedthrough capacitance of the gyrator.

According to a second aspect of the present invention there is provided a filter comprising at least one stage including first and second shunt capacitors and a series inductance stage, characterised in that the series inductance stage comprises first and second balanced gyrators and a shunt capacitance and in that each of the first and second gyrators comprises a plurality of interconnected feedforward and feedback MOS single-ended transconductors, balanced inputs and outputs, common mode feedback means coupled respectively between the balanced inputs and outputs, and means for providing each of the transconductors with a non-reciprocal feedback capacitance for rendering reciprocal the feedthrough capacitance of the transconductor thereby neutralising the feedthrough capacitance of the gyrator.

According to a third aspect of the present invention there is provided a transceiver having at least one channel filter, the or each channel filter comprising a plurality of balanced gyrators, each balanced gyrator including a plurality of interconnected feedforward and feedback MOS single-ended transconductors, balanced inputs and outputs, common mode feedback means coupled respectively between the balanced inputs and outputs, and means for providing each of the transconductors with a non-reciprocal feedback capacitance for rendering reciprocal the feedthrough capacitance of the transconductor thereby neutralising the feedthrough capacitance of the gyrator.

According to a further aspect of the invention there is provided a device comprising a balanced gyrator in accordance with the first aspect of the invention or a filter in accordance with the second aspect of the invention or a transceiver in accordance with the third aspect of the invention. Such a device may be, for example, an integrated circuit.

### BRIEF DESCRIPTION OF DRAWINGS

The present invention will now be described, by way of example, with reference to the accompanying drawings, wherein:

FIG. 1 is a block schematic diagram showing a gyrator comprising a feedback pair of transconductors,

FIG. 2 is a diagram of a balanced class AB transconductor comprising MOS transistor pairs and a common-mode feedback circuit,

FIG. 3 is a block schematic diagram of a balanced gyrator block comprising two balanced transconductors as shown in FIG. 2,

FIG. 4 is a diagram of a MOSFET showing the various intrinsic and extrinsic capacitances between pairs of electrodes,

FIG. 5 is a graph illustrating the intrinsic capacitances of the transistors of the transconductor in various operating regions,

FIG. 6 is a schematic circuit diagram of a single ended transconductor with an added feedback circuit,

FIG. 7 is a block schematic circuit diagram of a balanced gyrator block comprising four of the single ended transconductors shown in FIG. 6 and common mode feedback stages,

FIG. 8 is a block schematic diagram of a fifth order gyrator filter,

FIG. 9 illustrates, in broken lines, the frequency response of a fifth order gyrator filter in which the gyrator feedforward capacitances are not neutralised and, in full lines, the frequency response of the fifth order gyrator filter in which the gyrator feedforward capacitances have been neutralised, and

FIG. 10 is a block schematic diagram of a transceiver having a polyphase filter employing balanced gyrators made in accordance with the present invention.

In the drawings the same reference numerals have been used to indicate corresponding features.

### MODES FOR CARRYING OUT THE INVENTION

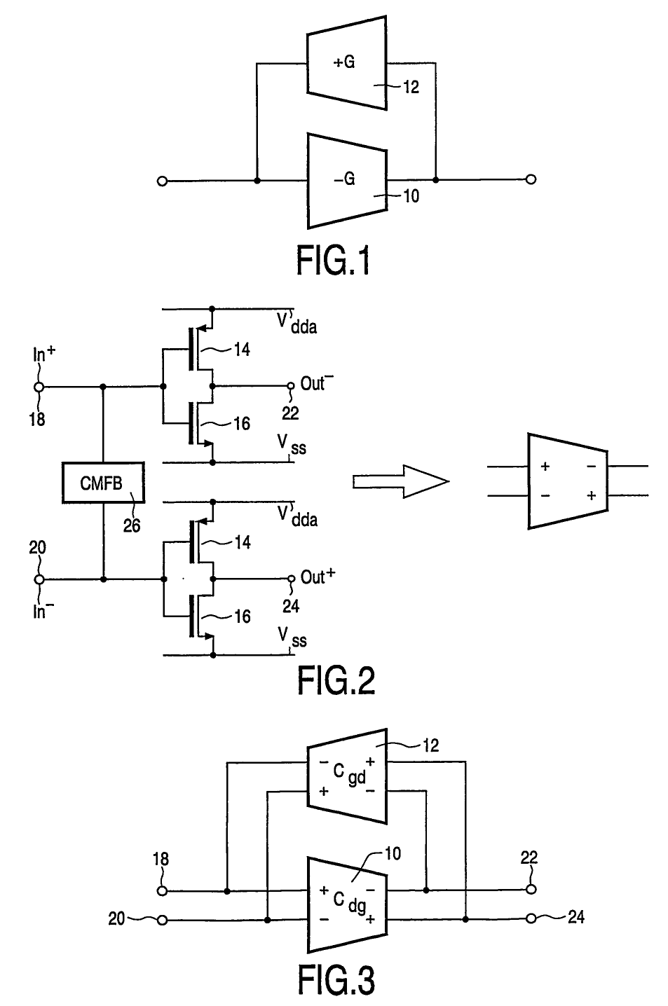

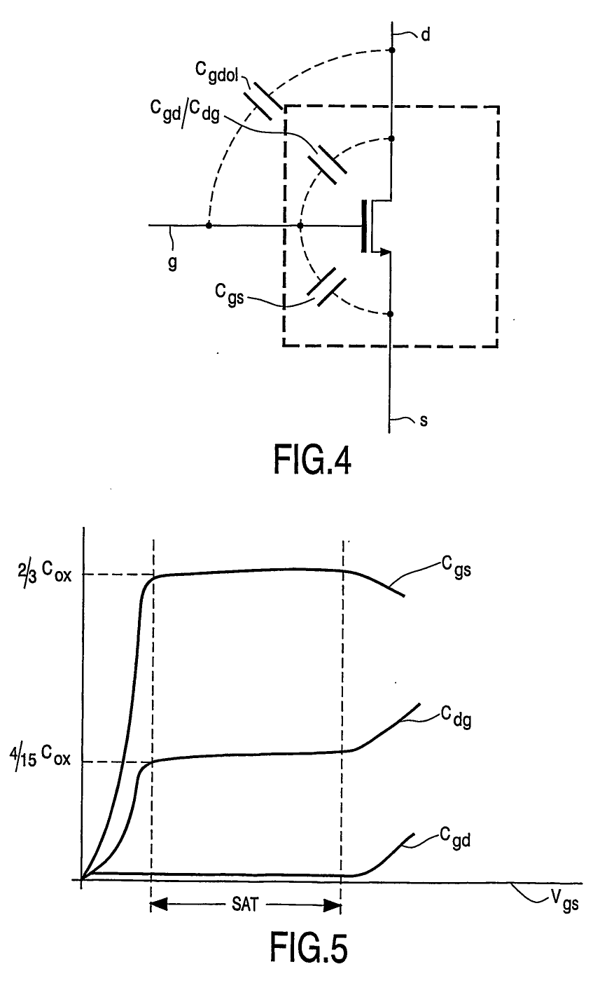

As FIGS. 1 to 5 have already been described in the preamble of the specification they will not be described again.

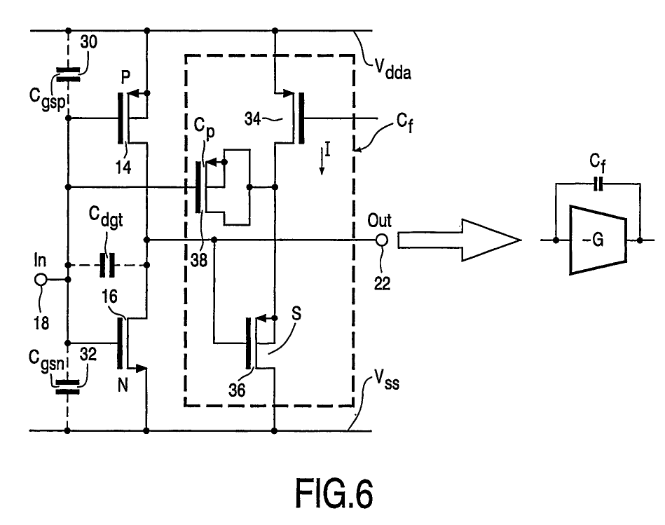

Referring to FIG. 6 the illustrated single ended transconductor comprises pMOS and nMOS transistors 14, 16, respectively, whose drain electrodes are connected together and whose source electrodes are connected to respective current supply rails V_{dda} and Vₛₛ. The gates of these transistors are connected to a common input terminal 18.

The gate-source capacitance 30 of the pMOS transistor 14, C_{gsp}, is shown in broken lines between the gate of the transistor 14 and the supply line V_{dda}. Similarly the gate-source capacitance 32 of the nMOS transistor 16, C_{gsn}, is shown in broken lines between the gate of the transistor 16 and the supply line Vₛₛ. The capacitance C_{dgt} between the interconnected drains and interconnected gates of the transistors 14, 16 is shown in broken lines.

The illustrated single ended transconductor further comprises an added feedback circuit C_{f}. This feedback circuit C_{f} comprises a source follower S, pMOS transistor 36, which is biased by a current source 1, pMOS transistor 34, and driven at its gate by the voltage at the transconductor output 22. The source follower output is connected to the transconductor input 18 by a capacitor Cₚ formed from the oxide capacitance of a MOS transistor 38. In the illustrated embodiment the transistor 38 is a PMOS transistor and if the transistor cuts-off due to signal polarity reversal the capacitance is fairly constant because the channel is replaced by the back-gate.

In a non-illustrated embodiment a reverse connected nMOS transistor (with its gate connected to the transconductor output 22 and common source-drain connected to the input 18) could be used to make the capacitor Cₚ. In that case, it should be biased permanently in its triode region using the source follower V_{gs}, transistor 36.

Reverting to the embodiment as illustrated, when a signal voltage is applied to the transconductor input 18, current flows by way of the capacitance C_{dgt} to the transconductor output 22 and by way of the capacitor Cₚ to the source follower S which routes it harmlessly to the Vₛₛ rail. So:

$${C}_{ff} = {C}_{dgt} = \frac{2}{5} ( {C}_{gsp} + {C}_{gsn} ) + {C}_{gdolp} + {C}_{gdoln} \qquad ( 6 )$$

When a signal voltage is applied to the transconductor output 22, current flows by way of the capacitance C_{gdt} and the capacitor Cₚ to the transconductor input 18. So:
C_{fb}=C_{gdt}+Cₚ=C_{gdolp}+C_{gdoln}+Cₚ (7)

If Cₚ is designed so that:

$$\begin{matrix}{C}_{p} = \frac{2}{5} ( {C}_{gsp} + {C}_{gsn} ) \\ then \text{:} & ( 8 ) \\ {C}_{ff} = {C}_{fb} = {C}_{f} & ( 9 )\end{matrix}$$

i.e. the feedthrough capacitance is now reciprocal.

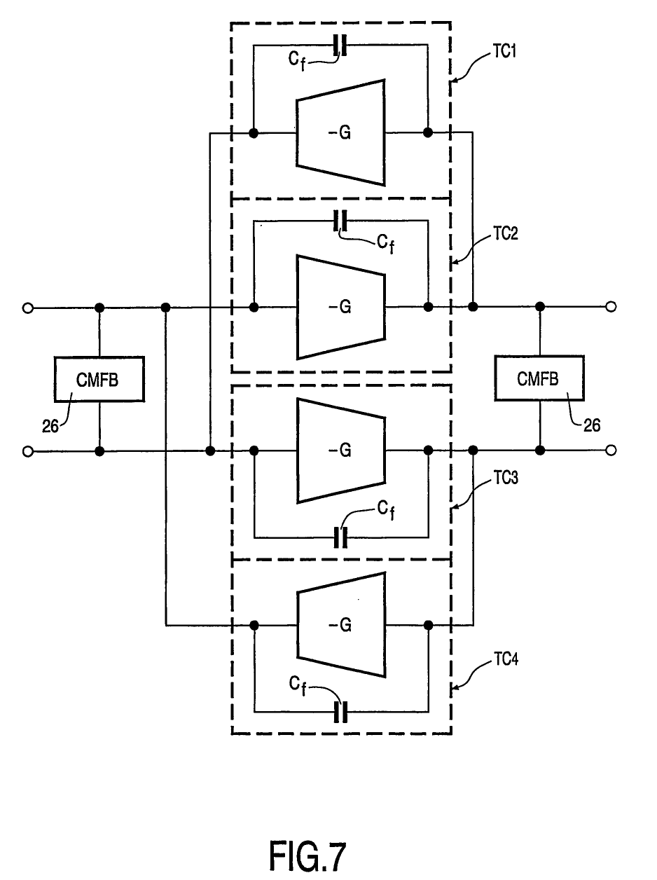

FIG. 7 is a block schematic diagram of a balanced gyrator comprising four single-ended transconductors TC1 to TC4 of the type shown in FIG. 6 in which the reciprocal capacitance is modelled by the capacitor C_{f} and common mode feedback (cmfb) circuits 26 connected across the input and output, respectively. The outputs of the transconductors TC1 and TC4 are coupled to inputs to the transconductors TC3 and TC2, respectively. As the balanced inputs 18, 19 and outputs 22, 23 always experience equal and opposite signal voltages, the currents fed through the capacitors C_{f} in the forward transconductor pair are always cancelled by the equal and opposite currents fed through the capacitors C_{f} in the feedback transconductor pair. In other words, the balanced gyrator feedthrough capacitors are self-neutralised. The cmfb circuits 26 serve to provide dc stabilisation.

The illustrated balanced gyrator circuit has been found to give a significant improvement to the frequency response of a Gm-C channel filter.

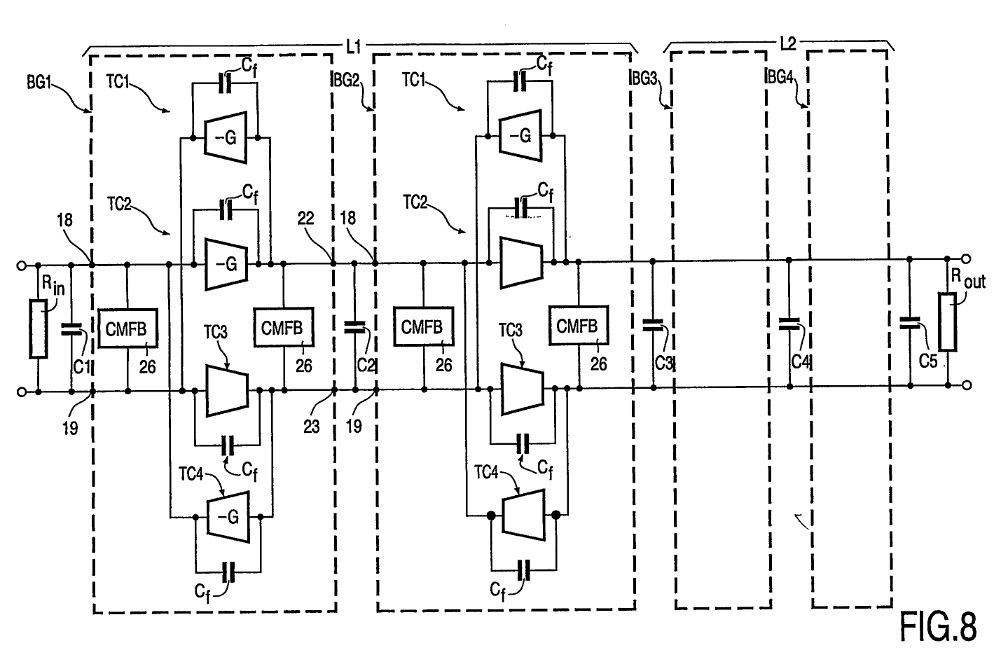

FIG. 8 shows a fifth order bandpass filter. The filter is an inductance/capacitance filter consisting of an input resistance R_{IN}, and output resistance R_{OUT}, shunt capacitors C1, C3 and C5 and series inductances L1, L2. The inductance L1 is implemented by balanced gyrators BG1, BG2 and a capacitor C2 and the inductance L2 by balanced gyrators BG3, BG4 and a capacitor C4, the balanced gyrators BG3, BG4 being constructed in the same manner as the balanced gyrators BG1, BG2. As the balanced gyrators BG1 to BG4 have been described with reference to FIG. 7, then in the interests of brevity they will not be described again.

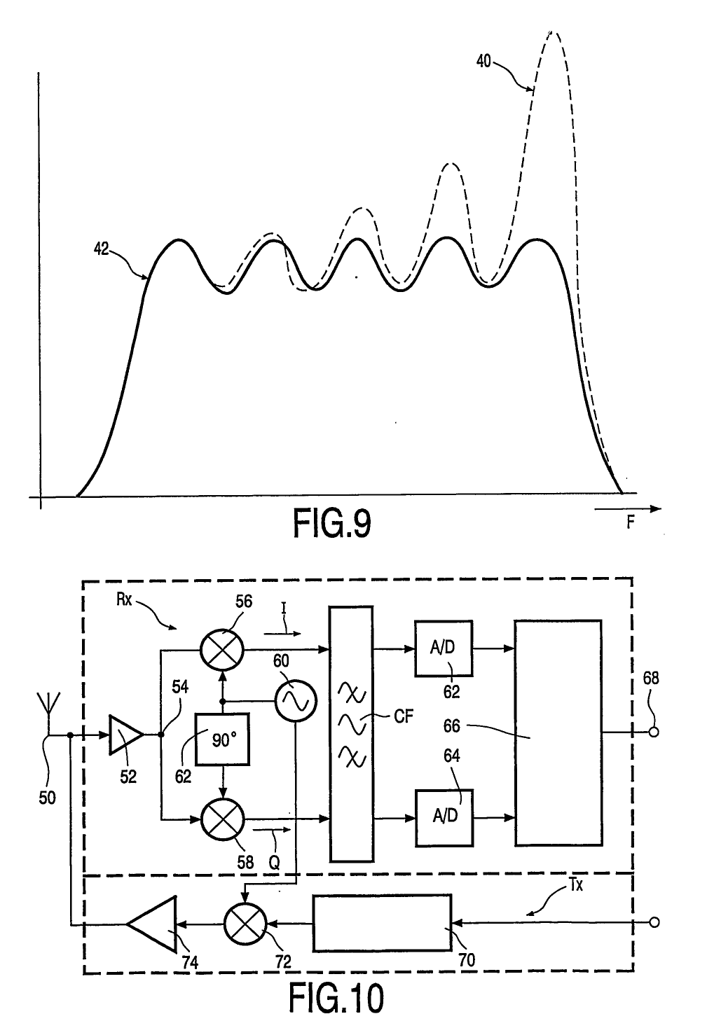

This improvement in the frequency response is illustrated in FIG. 9 in which the broken line frequency response 40 shows the effect of the feedthrough capacitors not being reciprocal, as demonstrated by equation (9) above, and the full line frequency response 42 illustrates the improvement when the capacitors are reciprocal.

The value of the capacitance Cₚ (FIG. 6) may be determined empirically by simulating the filter containing balanced gyrators having single-ended transconductors of the type shown in FIG. 6 together with the cmfb circuits 26 and varying the size of the transistors 38 until the desired performance is achieved.

FIG. 10 illustrates a transceiver in which a polyphase channel filter CF in the receiver section Rx comprises a Gm-C filter based on the fifth order bandpass filter shown in FIG. 8. More particularly the polyphase channel filter CF comprises two fifth order bandpass filters, one for each of the quadrature related phases, with the addition of cross branch balanced gyrators coupling corresponding capacitors, that is C1, C1; C2, C2 and so on, to create extra susceptance.

An antenna 50 is coupled to a low noise amplifier (LNA) 52 in the receiver section Rx. An output of the LNA 52 is coupled by way of a signal divider 54 to first inputs of quadrature related mixers 56, 58. A local oscillator signal generated by a signal generator 60 is applied to a second input of the mixer 56 and, by way of a ninety degree phase shifter 62, to a second input of the mixer 58. Quadrature related outputs 1, Q, respectively, from the mixers 56, 58 are applied to the polyphase channel filter CF which passes the wanted quadrature related signals to respective analogue-to-digital converters 62, 64. The digital outputs from the A-to-D converters 62, 64 are applied to a digital demodulator 66 which provides an output signal on a terminal 68.

The transmitter Tx comprises a digital modulator 70 which includes a digital-to-analogue converter (not shown) providing an analogue signal to a mixer 72 for frequency up-conversion to the required transmission frequency. A power amplifier 74 amplifies the frequency up-converted signal and supplies it to the antenna 50.

The transceiver including the channel filter CF may be fabricated as an integrated circuit using known low voltage CMOS processes.

In the present specification and claims the word “a” or “an” preceding an element does not exclude the presence of a plurality of such elements. Further, the word “comprising” does not exclude the presence of other elements or steps than those listed.

### INDUSTRIAL APPLICABILITY

Electronic circuits comprising a gyrator, such as gyrator filters and integrated transceivers including gyrators.

1. A balanced gyrator comprising a plurality of interconnected feedforward and feedback MOS single-ended transconductors, balanced inputs and outputs, common mode feedback means coupled respectively between the balanced inputs and outputs, and means for providing each of the transconductors with a non-reciprocal feedback capacitance for rendering reciprocal the feedthrough capacitance of the transconductor thereby neutralising the feedthrough capacitance of the gyrator.

2. A balanced gyrator as claimed in claim 1, wherein each of the single-ended transconductors comprises a pMOS transistor and a nMOS transistor having drain electrodes connected together, source electrodes connected to respective first and second power supply lines, gate electrodes coupled to an input, and a junction of the interconnected drain electrodes connected to an output, characterised in that the non-reciprocal feedback capacitance comprises a capacitive device coupled between the input and output.

3. A balanced gyrator as claimed in claim 2, characterised in that the capacitive device comprises a MOS transistor having its source and drain electrodes connected together and a gate electrode, in that the gate electrode is coupled to the transconductor input and in that a source follower transistor couples the interconnected source and drain electrodes to the transconductor output.

4. A balanced gyrator as claimed in claim 3, characterised in that the capacitance value of the capacitive device is related to the sum of the gate-source capacitances of the pMOS and nMOS transistors.

5. A balanced gyrator as claimed in claim 4, characterised in that the capacitance value is substantially equal to:
$$\frac{2}{5} ( {C}_{gsp} + {C}_{gsn} ) ,$$
where C_{gsp} and C_{gsn}, respectively are the gate-source capacitances of the pMOS and nMOS transistors.

6. A filter comprising at least one stage including first and second shunt capacitors and a series inductance stage, characterised in that the series inductance stage comprises first and second balanced gyrators and a shunt capacitance and in that each of the first and second gyrators comprises a plurality of interconnected feedforward and feedback MOS single-ended transconductors, balanced inputs and outputs, common mode feedback means coupled respectively between the balanced inputs and outputs, and means for providing each of the transconductors with a non-reciprocal feedback capacitance for rendering reciprocal the feedthrough capacitance of the transconductor thereby neutralising the feedthrough capacitance of the gyrator.

7. A transceiver having at least one channel filter, the or each channel filter comprising a plurality of balanced gyrators, each balanced gyrator including a plurality of interconnected feedforward and feedback MOS single-ended transconductors, balanced inputs and outputs, common mode feedback means coupled respectively between the balanced inputs and outputs, and means for providing each of the transconductors with a non-reciprocal feedback capacitance for rendering reciprocal the feedthrough capacitance of the transconductor thereby neutralising the feedthrough capacitance of the gyrator.

8. A transceiver as claimed in claim 7, wherein each of the single-ended transconductors comprises a PMOS transistor and a nMOS transistor having drain electrodes connected together, source electrodes connected to respective first and second power supply lines, gate electrodes coupled to an input, and a junction of the interconnected drain electrodes connected to an output, characterised in that the non-reciprocal feedback capacitance comprises a capacitive device coupled between the input and output.

9. A transceiver as claimed in claim 8, characterised in that the capacitive device comprises a MOS transistor having its source and drain electrodes connected together and a gate electrode, in that the gate electrode is coupled to the transconductor input and in that a source follower transistor couples the interconnected source and drain electrodes to the transconductor output.

10. A transceiver as claimed in claim 8, characterised in that the capacitance value of the capacitive device is related to the sum of the gate-source capacitances of the pMOS and nMOS transistors.

11. An integrated circuit comprising a filter as claimed in claim 6.

12. An integrated circuit comprising a transceiver as claimed in claim 1.
